(19) United States
(12) Patent Application Publication
(10) Pub. No.: US 2025/0314949 A1
(43) Pub. Date: Oct. 9, 2025

(54) CABINET FOR SURVEILLANCE CAMERA

(71) Applicant: HANWHA VISION CO., LTD., Seongnam-si (KR)

(72) Inventors: Byeong Ho LEE, Seongnam-si (KR); Ho Seoung HWANG, Seongnam-si (KR); Jin Hyuk CHOI, Seongnam-si (KR); Dong Woo KIM, Seongnam-si (KR)

(73) Assignee: HANWHA VISION CO., LTD., Seongnam-si (KR)

(21) Appl. No.: 19/169,436

(22) Filed: Apr. 3, 2025

(30) Foreign Application Priority Data
Apr. 5, 2024 (KR) 10-2024-0046959

(51) Int. Cl. G03B 17/56; F16M 11/04

(52) U.S. Cl. CPC G03B 17/561; F16M 11/046

(57) ABSTRACT

A cabinet may include a body, a bracket connected to a rear surface of the body, and a cover connected to a front surface of the body to be opened and closed, wherein the body may include a first accommodation groove at a rear edge of the body, the bracket may include an insertion protrusion corresponding to the first accommodation groove and a support protrusion at the edge of the bracket to face a rear surface of the body at a position spaced apart from the first accommodation groove. The body may slide to a second position from a state where the body is temporarily fixed to the bracket at a first position.

### CROSS-REFERENCE TO RELATED APPLICATION

This application is based on and claims priority under 35 U.S.C. § 119 to Korean Patent Application No. 10-2024-0046959, filed on Apr. 5, 2024, in the Korean Intellectual Property Office, the disclosure of which is incorporated by reference herein in its entirety.

### BACKGROUND

### 1. Field

Some embodiments of the present disclosure relate to a cabinet for a surveillance camera.

### 2. Description of Related Art

A surveillance camera may be installed on a wall, a ceiling, or in a corner between the wall and the ceiling so that a field of view of the surveillance camera is not obstructed. The surveillance camera may be installed directly on a structure or installed on the structure via a cabinet. The cabinet may include a controller for operating and controlling the surveillance camera, an injector, various wires, and the like, and may include components for connecting the surveillance camera to the structure.

When installing a surveillance camera on a structure via a cabinet, a cable may be connected to the cabinet first with the cabinet temporarily fixed to the structure, and then the cabinet may be finally secured on the structure. However, in the related art, since the cabinet is temporarily fixed to the structure and then the cable is arranged and connected, and the cabinet is separated from the structure again and then finally fixed to the structure again, the installation of the cabinet and arrangement of the cable are cumbersome. In addition, in the process of connecting the cabinet to the structure, there are problems such as separation of the cabinet from the designated position.

The above information is provided only for improving understanding of the background of present disclosure, and thus may include information that does not constitute prior art.

### SUMMARY

According to embodiments of the present disclosure, a cabinet for a surveillance camera may be provided, wherein the cabinet may allow fixing of a bracket to a body of the cabinet without separation of the body from the bracket after arranging a cable while temporarily fixing the bracket to the body.

According to embodiments of the present disclosure, a cabinet for a surveillance camera may be provided and include: a body; a bracket configured to be connected to a rear surface of the body; and a cover configured to be connected to a front surface of the body to be opened and closed, wherein the body includes at least one first accommodation groove in a rear edge of the body, wherein the bracket includes: at least one insertion protrusion respectively corresponding to the at least one first accommodation groove, and at least one support protrusion at an edge of the bracket to face the rear surface of the body at a position spaced apart from the at least one first accommodation groove, wherein the body is configured to be coupled to the bracket at a first position with respect to the bracket, and then at a second position with respect to the bracket, wherein, in a case where the body is coupled to the bracket at the first position, the at least one insertion protrusion is respectively accommodated in the at least one first accommodation groove, the at least one support protrusion supports the body, and the body is temporarily fixed to the bracket at the first position, and wherein the body is configured to, while the body is separated from the at least one support protrusion, move to the second position by sliding downward along the bracket, in a height direction of the bracket.

According to one or more embodiments of the present disclosure, in a case where the body moves from the first position to the second position, at least a part of each of the at least one insertion protrusion accommodated in the at least one first accommodation groove at the first position is maintained in the at least one first accommodation groove.

According to one or more embodiments of the present disclosure, the body further includes a first rib extending continuously or discontinuously along an outer edge of the rear surface, wherein the at least one first accommodation groove is spaced apart from the first rib toward an inside of the body, and a sliding gap is defined by and between the first rib and the at least one first accommodation groove, and wherein the at least one support protrusion is configured to be inserted into the sliding gap.

According to one or more embodiments of the present disclosure, the body further includes a body cover, and at least a part of the body cover is spaced apart from the rear surface of the body, wherein the at least one first accommodation groove is between the rear surface of the body and the body cover, wherein a lower part and a side part of the at least one first accommodation groove are open to an outside of the body, and wherein the at least one insertion protrusion is configured to be inserted into and detached from the at least one first accommodation groove through the lower part and the side part of the at least one first accommodation groove.

According to one or more embodiments of the present disclosure, the body further includes a seating groove that is concave in the rear surface of the body and corresponds to the body cover.

According to one or more embodiments of the present disclosure, each of the at least one insertion protrusion includes: a first portion extending in a first direction from the bracket; and a second portion extending from the first portion in a second direction intersecting the first direction, wherein the first portion is configured to be inserted into the sliding gap, and wherein the second portion is configured to be inserted into the at least one first accommodation groove.

According to one or more embodiments of the present disclosure, the at least one first accommodation groove includes a plurality of first accommodation grooves that are at opposite edges of the rear surface of the body, wherein the at least one insertion protrusion includes a plurality of insertion protrusions that are at opposite edges of the bracket and correspond to the plurality of first accommodation grooves, wherein the body further includes a hook between the plurality of first accommodation grooves and connected to the rear surface of the body, and wherein the at least one support protrusion is between the plurality of insertion protrusions in the height direction of the bracket.

According to one or more embodiments of the present disclosure, the hook is configured to, in a case where the hook is pressed in a width direction of the body while the body is at the first position, deform and separate from a top of the at least one support protrusion, and wherein the body is configured to move with respect to the bracket based on the hook deforming and separating from the top of the at least one support protrusion.

According to one or more embodiments of the present disclosure, the body further includes a second accommodation groove in a side surface of the body and the rear surface of the body, and wherein the hook includes: a hook body configured to be inserted into the second accommodation groove; and a deformable body configured to be inserted into the second accommodation groove, the deformable body extending from the hook body and including an elastic material.

According to one or more embodiments of the present disclosure, the hook further includes a hook protrusion protruding from the hook body toward the body, wherein the hook protrusion is configured to be supported on the at least one support protrusion while the body is at the first position, and wherein, based on the hook body being pressed, the deformable body is configured to be deformed and the hook protrusion is configured to be separated from the at least one support protrusion.

According to one or more embodiments of the present disclosure, the body further includes a second rib extending along an edge of the second accommodation groove and protruding from the rear surface of the body, and wherein the deformable body includes an end portion that has a curved shape, and the second rib is configured to support the end portion of the deformable body.

According to one or more embodiments of the present disclosure, the second accommodation groove includes a connection protrusion, and wherein the hook body includes an insertion hole that is configured to receive the connection protrusion, and the insertion hole has an elongated shape in a moving direction of the hook, and wherein the hook is configured to, based on the hook being pressed, move in the moving direction while the connection protrusion is in the insertion hole.

According to one or more embodiments of the present disclosure, the at least one insertion protrusion includes four insertion protrusions, and a respective two of the four insertion protrusions are on each of opposite side edges of the bracket in a width direction of the bracket, and wherein the at least one support protrusion is between the respective two insertion protrusions in a height direction of the body.

According to one or more embodiments of the present disclosure, wherein, in the case where the body is coupled to the bracket at the first position, the at least one insertion protrusion is in the at least one first accommodation groove, respectively, and spaced apart from a top end of the at least one first accommodation groove, respectively, and the hook is supported on the at least one support protrusion, and wherein, in a case where the body is coupled to the bracket at the second position, the at least one insertion protrusion is in the top end of the at least one first accommodation groove, respectively, and the hook is below the at least one support protrusion that supports the hook at the first position.

According to one or more embodiments of the present disclosure, each of the at least one insertion protrusion includes a first insertion protrusion, and a second insertion protrusion below the first insertion protrusion in the height direction of the bracket, and wherein the at least one support protrusion includes: a first support protrusion configured to support the hook while the body is coupled to the bracket at the first position; a second support protrusion configured to be between the first support protrusion and the first insertion protrusion while the body is coupled to the bracket; a third support protrusion configured to be between the second support protrusion and the second insertion protrusion while the body is coupled to the bracket, and a fourth supporting protrusion configured to be below the second insertion protrusion while the body is coupled to the bracket.

According to one or more embodiments of the present disclosure, the cabinet further includes a plurality of couplers including a plurality of first couplers that are configured to connect the body to the cover, wherein the plurality of first couplers includes: a body coupler extending from the body and including a first concave portion and a first protrusion, a cover coupler including a second concave portion and a second protrusion, wherein the first concave portion is configured to engage with the second protrusion, and the second concave portion is configured to engage with the first protrusion; a shaft configured to be inserted into the first protrusion and the second protrusion in a state in which the first concave portion and the second protrusion are engaged with each other and the first concave portion and the second protrusion are engaged with each other, and wherein the second protrusion is configured to limit a rotation angle of the cover with respect to the body by the second protrusion being in contact with the first concave portion.

According to one or more embodiments of the present disclosure, the plurality of couplers further includes a second coupler configured to connect the body to the cover, and wherein the second coupler is spaced apart from the plurality of first couplers, is between the plurality of first couplers, and includes a torque hinge.

According to one or more embodiments of the present disclosure, the body includes a body hole that is configured to receive a cable, wherein the bracket includes, at a lower portion of the bracket, a bracket hole corresponding to the body hole, wherein the body hole is configured to receive the cable via the bracket hole while the body is at the first position, and wherein the body is configured to be moved to the second position after the cable is inserted into the body hole through the bracket hole.

According to embodiments of the present disclosure, a cabinet for a surveillance camera may be provided and include: a body including a first accommodation groove; and a bracket including an insertion protrusion, wherein the body is configured to be at an initial position with respect to the bracket where the insertion protrusion is not inserted into the first accommodation groove, wherein the body is configured to be lowered from the initial position, by its own weight, to a first position with respect to the bracket, wherein, at the first position, the insertion protrusion is partially in the first accommodation groove, wherein the body is configured to, in a case where the body is at the first position and pressed, lowered by its own weight to a second position with respect to the bracket, wherein, at the second position, an amount of the insertion protrusion within the first accommodation groove is increased in comparison to when the body is at the first position, and wherein the body is configured to not be separated from the bracket while the bracket is moving from the first position to the second position.

According to embodiments of the present disclosure, a cabinet for a surveillance camera may be provided and include: a body including a hook; and a bracket including a support protrusion, wherein the body is configured to be at an initial position with respect to the bracket, wherein the body is configured to be lowered from the initial position, by its own weight, to a first position with respect to the bracket, wherein, at the first position, the hook is supported by the support protrusion, wherein the hook is configured to be pressed toward an inside of the body while the body is at the first position to deform the hook and separate the hook from the support protrusion, wherein the body is configured to be lowered to a second position with respect to the bracket based on the hook being separated from the support protrusion, and wherein the support protrusion is configured to remain in the body while the body moves from the first position to the second position.

Technical problems that are solved by embodiments of the present disclosure are not limited to the above-described problems, and other problems, not mentioned, that are solved by embodiments of the present disclosure may be clearly understood by those skilled in the art from the below description.

Additional aspects will be set forth in part in the description which follows and, in part, will be apparent from the description, or may be learned by practice of example embodiments of the present disclosure.

### BRIEF DESCRIPTION OF DRAWINGS

The following drawings illustrate non-limiting example embodiments of the present disclosure and serve to describe example aspects of the present disclosure together with the detailed description of the present disclosure provided below. Embodiments of the present disclosure are not limited to the configurations shown in the drawings.

The above and other aspects, features, and advantages of certain embodiments of the present disclosure will be more apparent from the following description taken in conjunction with the accompanying drawings, in which:

FIG. 1 illustrates a state in which a cabinet according to embodiments is used to connect a surveillance camera and a structure to each other;

FIG. 2 is a perspective view illustrating a cabinet according to embodiments;

FIG. 3 is a side view illustrating a cabinet according to embodiments;

FIG. 4 illustrates one surface of a body according to embodiments;

FIG. 5 is an enlarged view of a portion V of FIG. 4;

FIG. 6 illustrates inner surfaces of a body according to embodiments;

FIG. 7 illustrates a bracket according to embodiments;

FIGS. 8 to 14 illustrate a sequence of mounting a body to a bracket according to embodiments;

FIG. 15 illustrates a fastening member inserted into a body and a bracket according to embodiments;

FIG. 16 illustrates a coupler of a cabinet according to embodiments; and

FIG. 17 illustrates a state in which a coupler rotates according to embodiments.

### DETAILED DESCRIPTION

Reference will now be made in detail to non-limiting example embodiments of the present disclosure, examples of which are illustrated in the accompanying drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain example aspects of the present description. As used herein, the term “and/or” includes any and all combinations of one or more of the associated listed items. Expressions such as “at least one of,” when preceding a list of elements, modify the entire list of elements and do not modify the individual elements of the list.

Embodiments of the present disclosure, including methods, may be more easily understood with reference to the detailed description of example embodiments together with the accompanying drawings. Hereinafter, non-limiting example embodiments will be described in detail with reference to the accompanying drawings. However, the example embodiments may be modified in various ways and may be implemented in different forms, and the present disclosure should not be construed as being limited to the example embodiments described herein. In addition, individual features of the various embodiments of the present disclosure may be combined or coupled partially or wholly with each other, enabling various technically interconnected and actuated operations. The respective embodiments may be implemented independently of each other or may be implemented together in association with each other. The described embodiments are provided as examples so that the present disclosure may be complete and to fully convey the idea of the present disclosure to those of ordinary skill in the art. The present disclosure should be understood as encompassing all modifications and equivalents, and modifications and equivalents may be substituted within the spirit and technical scope of the present disclosure. Thus, processes, components, techniques, and the like not required by one of ordinary skill in the art for a complete understanding of embodiments of the present disclosure may not be described.

Unless otherwise stated, throughout the accompanying drawings and descriptions, the same reference numbers, letters, or combinations thereof represent the same components, and repeated descriptions thereof may be omitted. In addition, irrelevant parts in describing example embodiments may not be shown in the drawings for clarity of explanation.

The shapes of features shown in the drawings may be schematic and the shapes may not limit the actual shape(s) of the features. The relative sizes of elements, layers, areas, and the like in the drawings may be exaggerated for clarity. In addition, the use of hatching and/or shading in the accompanying drawings may generally be provided to clarify the boundaries between adjacent elements. As such, unless otherwise defined, neither the presence nor the absence of cross-hatching or shading indicates any preference or requirement for particular materials, material properties, dimensions, proportions, commonalities between illustrated elements, and/or any other characteristic, attribute, property, etc., of the elements.

Various embodiments are described herein with reference to cross-sectional examples that are schematic examples of embodiments and/or intermediate structures. For example, the shapes in the drawings may vary as a result of manufacturing techniques and/or tolerances. Furthermore, the specific structural or functional description described herein is merely an example for explaining an example embodiment according to the present disclosure. Therefore, embodiments of the present disclosure are not limited to the illustrated shapes, and embodiments should be construed as including a deviation of the shape(s) according to a manufacturing process or the like.

Specific details may be presented in the specification for understanding various embodiments. Alternatively, various embodiments may be implemented without these specific details or including one or more details. In other cases, well-known structures and devices may be shown in block diagram form to avoid unnecessarily obscuring various embodiments.

As illustrated in the drawings, spatially relative terms such as “down,” “up,” “lower portion,” “down,” “upper portion,” and the like may be used here to facilitate description of the relationship between one element or feature and another element or feature. The spatially relative terms are intended to include various directions of the device in use or operation in addition to the directions shown in the drawings. For example, if the device in the figures is turned over, elements described as “below,” “beneath,” “or “under” other elements or features would then be oriented “above” the other elements or features. Thus, as illustrative terms, “down” and “lower portion” may include both up and down directions. The device may be directed in a different direction (e.g., 90° rotation or another direction), and the spatially relative description used herein should be interpreted accordingly. Likewise, when it is stated that a first portion is positioned “above” a second portion, this means that the first portion is positioned above or below the second portion.

In addition, the expression “viewed from a plane” means the case where the object is viewed from above, and the expression “in an approximate cross-sectional view” means the case where the object is cut vertically or horizontally to take a rough cross-section. The term “as viewed from the side” means that the first object may be above, below, or on the side of the second object and vice versa. Additionally, the term “overlap” may include layer, stack, face or facing, extending over, covering, or partly covering or any other suitable term as would be appreciated and understood by those of ordinary skill in the art. The expression “non-overlapping” may include meanings such as “apart from” or “separated from” and any other suitable equivalents recognized and understood by one of ordinary skill in the art. The term “face” may mean that a first object may directly or indirectly face a second object. When there is a third object between a first object and a second object, it may be understood that the first object and the second object face each other indirectly.

When an element, layer, region, or component (hereinafter referred to as “element, etc.”) is referred to as “formed,” “connected,” or “combined” to another element, etc., it includes being formed directly on another element, etc., formed on another element, etc., formed indirectly on another element, etc., connected to another element, etc., or combined with another element, etc. In addition, “formed,” “connected,” or “combined” may collectively refer to a direct or indirect combination or connection, or an integral or non-integral combination or connection. For example, when an element, etc., is referred to as “electrically connected” or “electrically combined” with another element, etc., this includes being directly connected or combined with another element, etc., or other elements, etc., may exist therebetween. However, “directly connected to” or “directly combined with” means that one element, etc., is connected or combined with another element, etc., directly without an intermediate element, or the former is on the latter. In addition, in the present disclosure, when a portion of a layer, film, region, guide plate, etc., is formed on another portion, the formation direction is not limited to the upper direction, and includes the portion being formed on the side or bottom. Conversely, when a portion of a layer, film, region, guide plate, etc., is formed “underneath” another portion, this includes not only the case where the portion is “directly under” the other portion, but also the case where there is still another portion between the portion and the other portion. Meanwhile, other expressions describing relationships between elements, etc., such as “between,” “immediately between” or “adjacent to” and “directly adjacent to” may be construed similarly. In addition, when an element, etc., is referred to as being “between” two elements, etc., the only element, etc., is present between the two elements, etc., or other intervening elements, etc., may also be present.

Expressions such as “at least one” or “any one” do not limit the order of individual elements. For example, “at least one of X, Y or Z,” “at least one of X, Y or Z,” “at least one selected from a group of X, Y and Z” may include X alone, Y alone, Z alone, and any combination of two or more of X, Y and Z. Similarly, expressions such as “at least one of A and B” and “at least one of A or B” may include A, B, or A and B. In the present disclosure, the term “and/or” generally includes all combinations of one or more related list items. For example, expressions such as “A and/or B” may include A, B, or both A and B.

Terms such as “first,” “second,” “third,” etc., may be used to describe various elements, etc., in the present application, but these elements, etc., are not limited by these terms. These terms are used to distinguish one element, etc., from another. Therefore, the “first” element, etc., described below may be referred to as the “second” element, etc., without departing from the spirit and scope of the present disclosure. The description of an element as a “first” element may not require or imply the presence of a second element or other elements. Terms such as “first,” “second,” and the like may be used in the present disclosure to distinguish between different categories or sets of elements, etc. For clarity, the terms “first,” “second,” etc., may represent “first category (or first set),” “second category (or second set),” etc., respectively.

The terms used herein are used only to describe particular example embodiments, and are not intended to limit the present disclosure. As used in the present disclosure, a singular expression is intended to include a plural expression as well, and a plural expression is also intended to include a singular expression unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the order described. For example, two processes described in succession may be performed substantially simultaneously, or may be performed in the opposite order to the order described.

Terms “substantially,” “about,” “approximately,” and similar terms are used as terms of approximation rather than degree, and mean satisfying the inherent range of variation in a measured or calculated value (e.g., the range of variation due to limitations of the measurement system). For example, terms such as “about” or “approximately” could mean within one or more standard deviations, or within ±30%, ±20%, ±10%, or ±5% of a specified value.

Unless otherwise defined, all terms used herein, including technical or scientific terms, have the same meaning as commonly understood by one of ordinary skill in the art to which the present disclosure pertains. Terms such as commonly used dictionary-defined terms shall be construed as having meaning consistent with their meaning in the context of the relevant technology and/or the present disclosure, and shall not be idealized or interpreted in an overly formal sense unless explicitly defined herein.

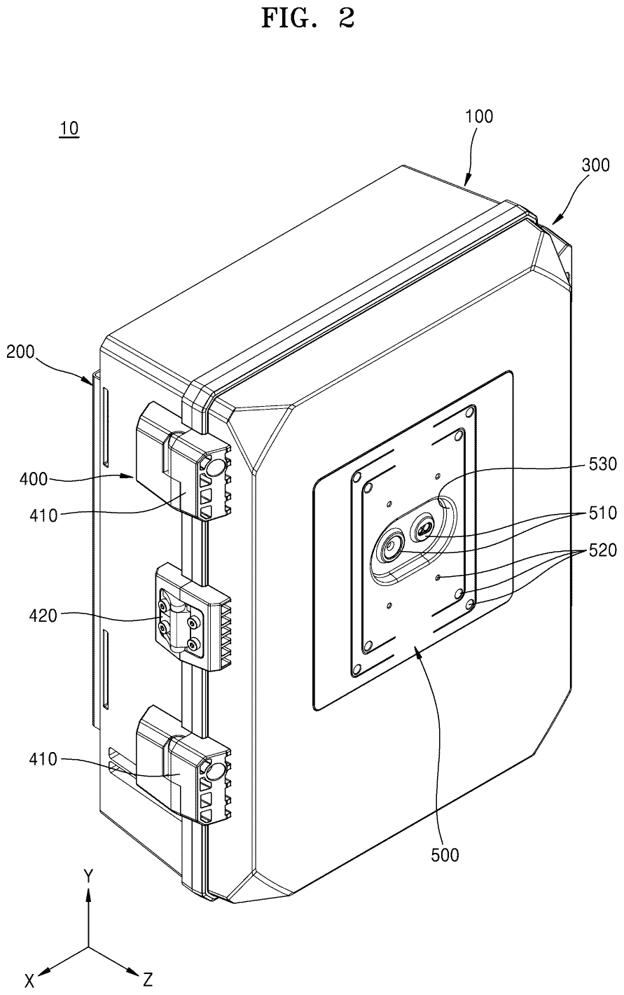

Unless particularly limited in the present disclosure, longitudinal, width, thickness, and height directions of a cabinet 10, a body 100, a bracket 200, and a cover 300, which are shown in FIG. 2, may be respectively the same as those of other components.

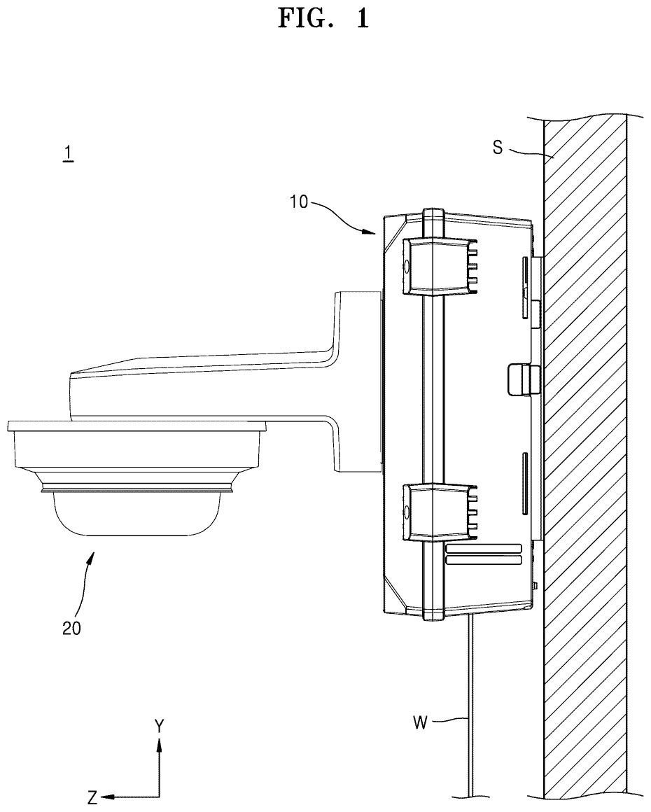

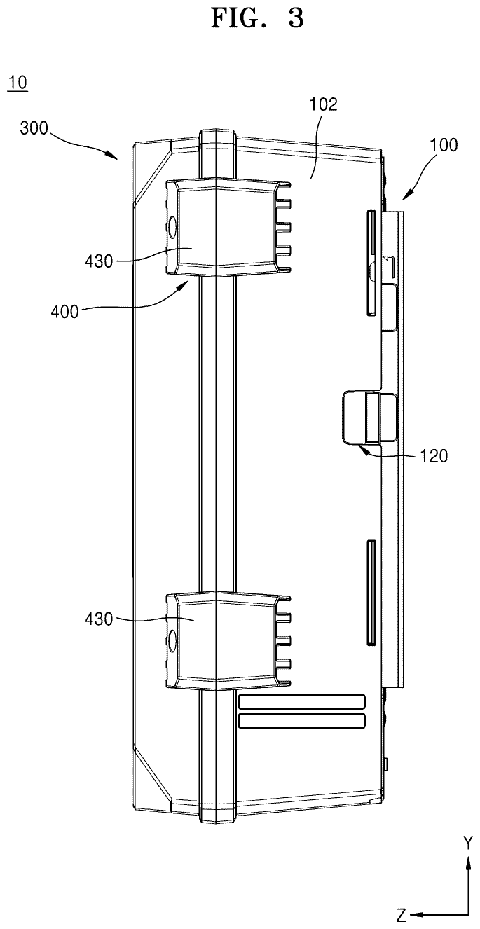

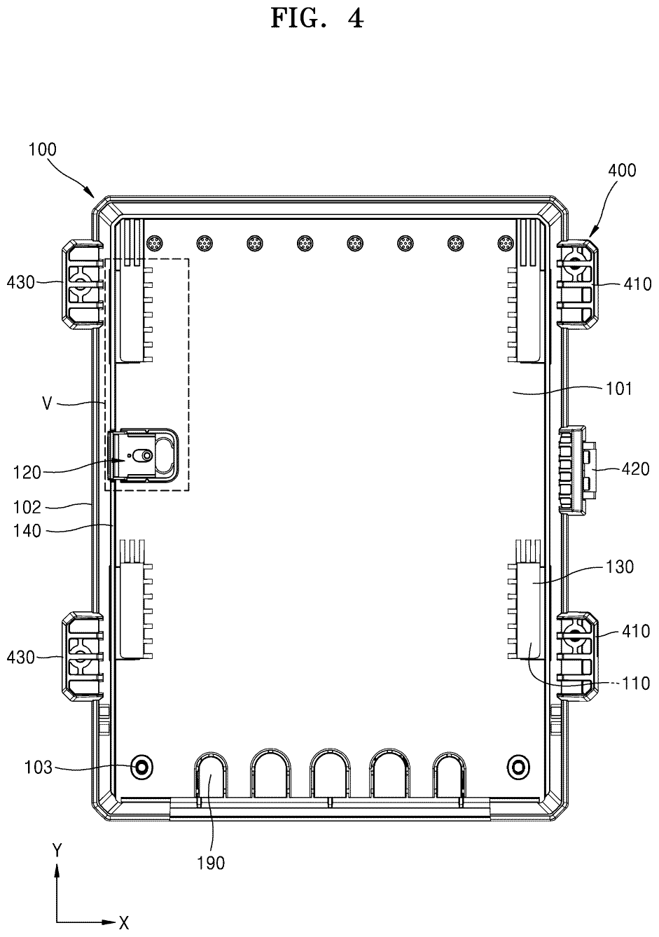

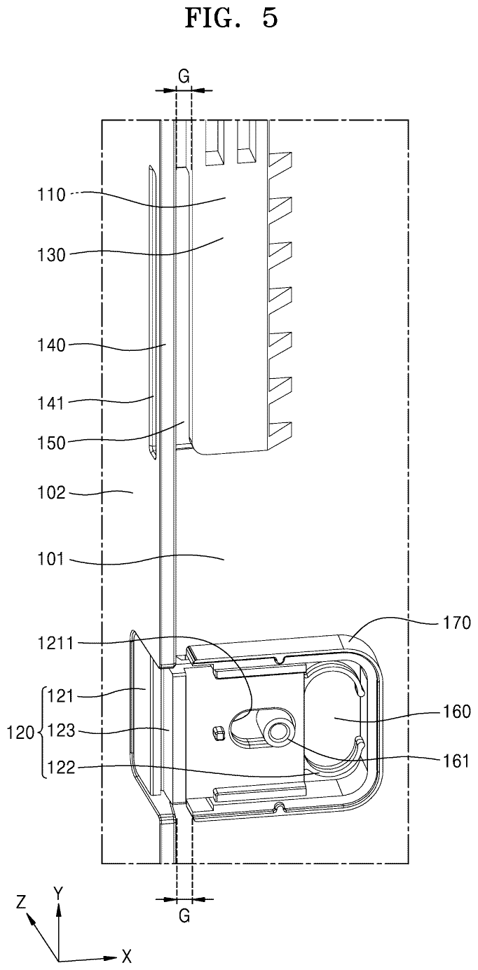

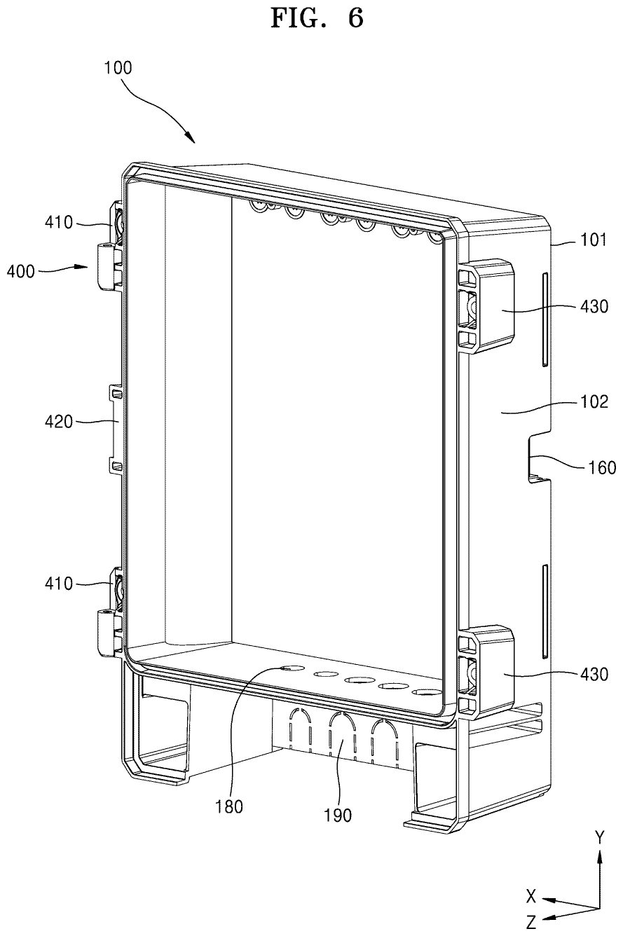

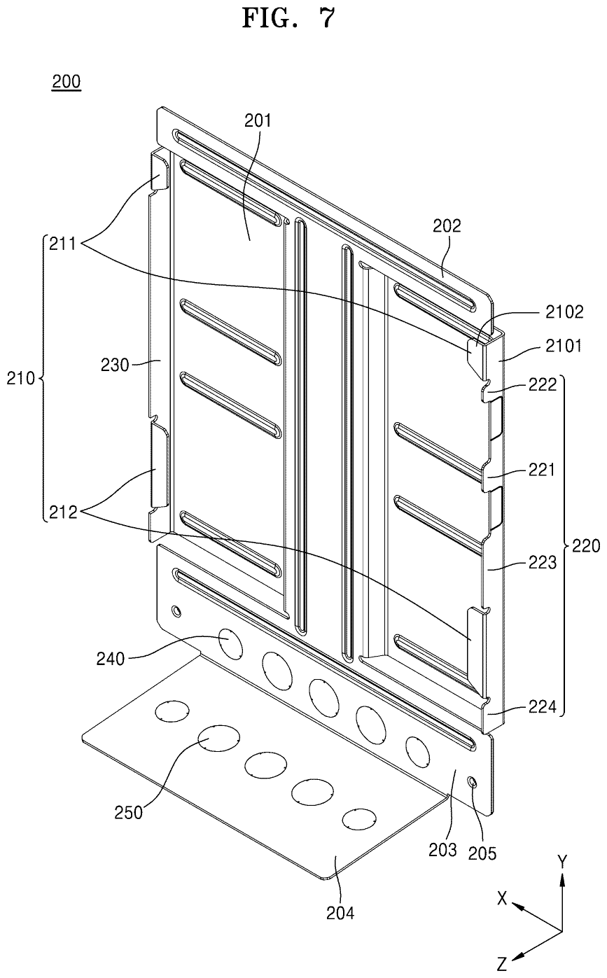

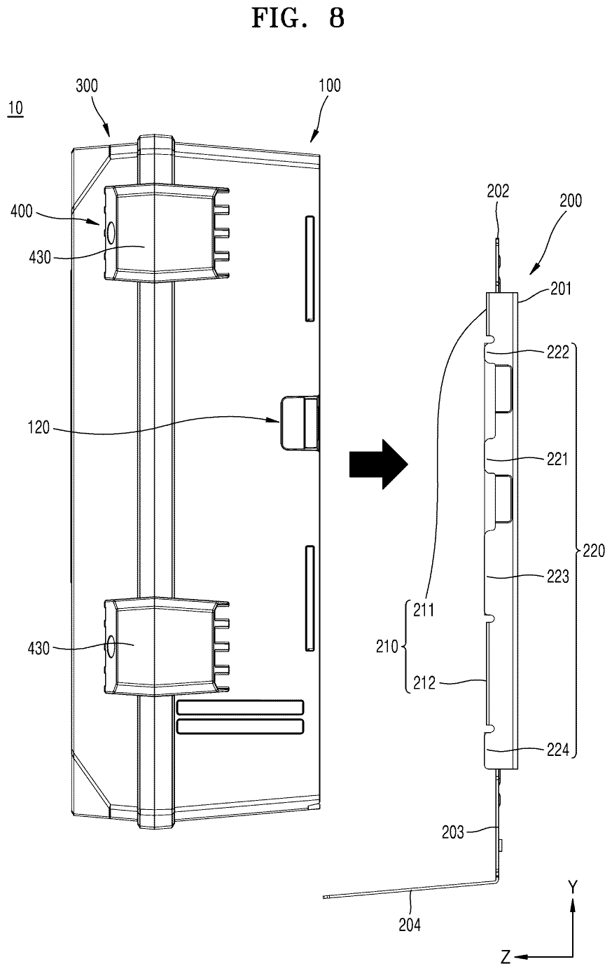

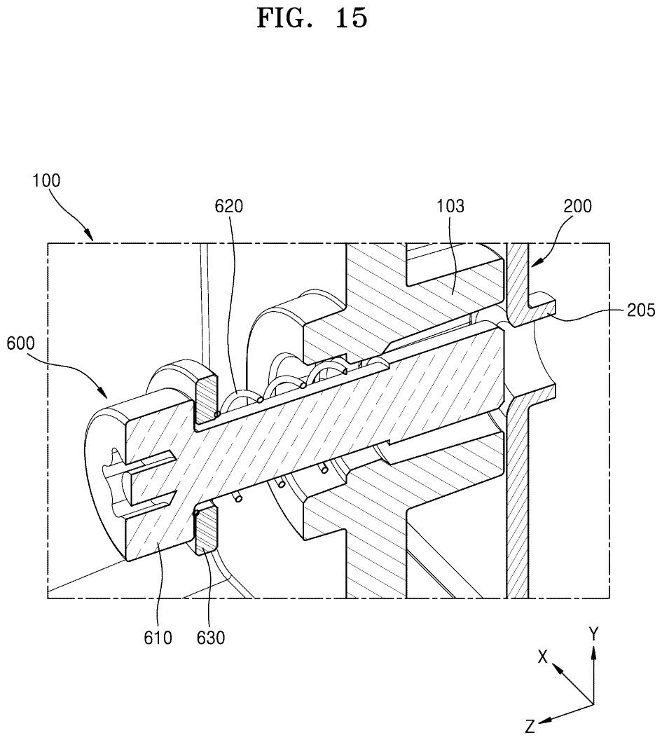

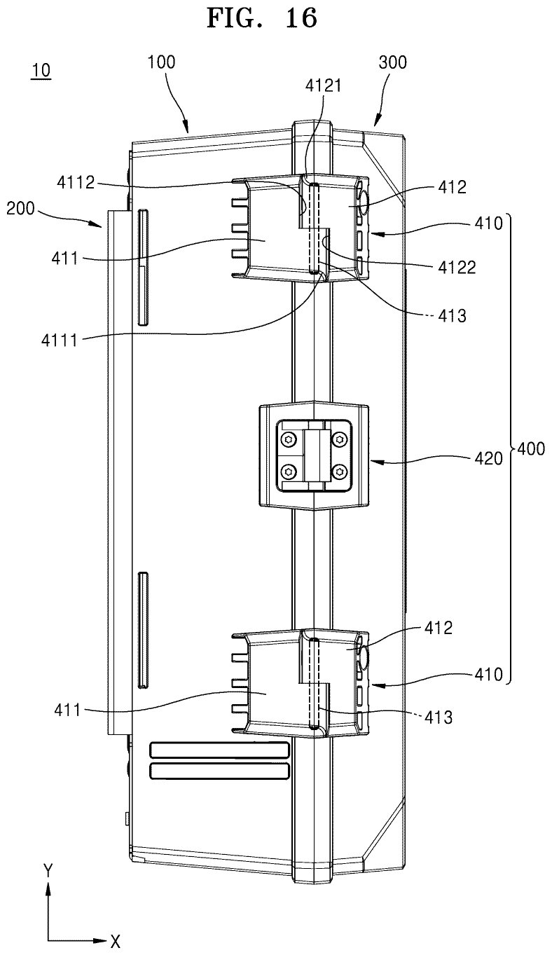

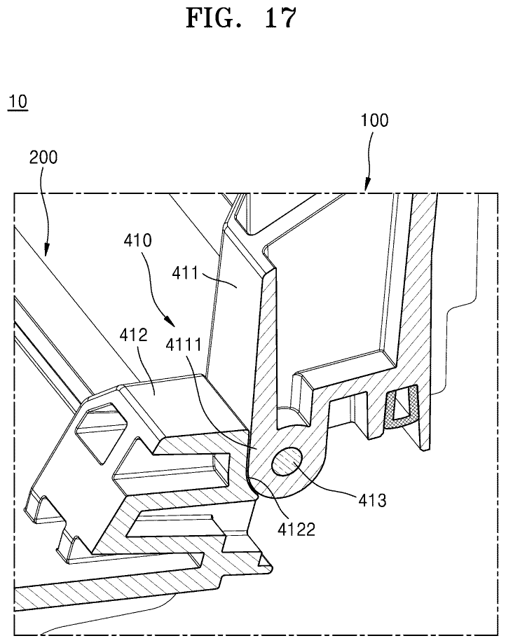

FIG. 1 illustrates a state in which the cabinet 10 according to embodiments is used to connect a surveillance camera 20 and a structure S to each other. FIG. 2 is a perspective view illustrating the cabinet 10 according to embodiments. FIG. 3 is a side view illustrating the cabinet 10 according to embodiments. FIG. 4 illustrates one surface of the body 100 according to embodiments. FIG. 5 is an enlarged view of a portion V of FIG. 4. FIG. 6 illustrates inner surfaces of the body 100 according to embodiments. FIG. 7 illustrates the bracket 200 according to embodiments. FIGS. 8 to 14 illustrate a sequence of mounting the body 100 to the bracket 200 according to embodiments. FIG. 15 illustrates a fastening member 600 inserted into the body 100 and the bracket 200 according to embodiments. FIG. 16 illustrates a coupler 400 of the cabinet 10 according to embodiments. FIG. 17 illustrates a state in which the coupler 400 rotates according to embodiments.

The cabinet 10 according to embodiments of the present disclosure may include components for connecting the surveillance camera 20 to the structure S and controlling the surveillance camera 20. For example, as shown in FIG. 1, the cabinet 10 may be included in a surveillance camera assembly 1 together with the surveillance camera 20. The cabinet 10 may be installed on the structure S such as a wall or ceiling, a pillar, or a corner area between the walls or ceilings, and may support the surveillance camera 20. The cabinet 10 may be installed on the structure S via welding, bolts, adhesives, or the like. The structure S may be an external device. In addition, the cabinet 10 may be connected to wires W including a power cable, an optical cable, and the like. One or more wires W may be inserted into the cabinet 10 and then connected to the surveillance camera 20 or to components inside the cabinet 10. The cabinet 10 may include a controller including a control circuit, a memory, a sensor, and the like, and an injector.

The cabinet 10 may include a body 100, a bracket 200, a cover 300, a coupler 400, and a connector 500, as shown in FIG. 2.

For example, the cabinet 10 may include the body 100, the bracket 200 connected to the rear surface of the body 100, and the cover 300 connected to the front surface of the body 100 to be openable and closable. The body 100 may include one or more first accommodation grooves 110 formed in the rear edge of the body 100 and a hook 120 connected to the rear surface of the body 100 between the one or more first accommodation grooves 110. The bracket 200 may include one or more insertion protrusions 210 corresponding to the one or more first accommodation grooves 110, and a plurality of support protrusions 220 formed at the edge of the bracket 200 to face a rear surface 101 of the body 100 between the one or more first accommodation grooves 110. In a state where the body 100 is coupled to the bracket 200 at a first position, the one or more insertion protrusions 210 may be accommodated in the one or more first accommodation grooves 110, respectively, and at least one of the plurality of support protrusions 220 may support the hook 120. When the body 100 is temporarily fixed to the bracket 200 at the first position, and the hook 120 is pressed at the first position, the hook 120 may be separated from the support protrusions 220, and the body 100 may slide downward along the bracket 200 toward a height direction of the bracket 200 to move to a second position.

The body 100 may hold and support other components of the cabinet 10 (e.g., the bracket 200 and the cover 300 or the controller, the wires W, etc.). For example, the body 100 may include an internal space in which various electrical/electronic equipment such as an injector or a control board is accommodated. In addition, in a state in which the body 100, the bracket 200, and the cover 300 are assembled, the wires W may be inserted into the inner space of the body 100 to be connected to electrical/electronic equipment. The body 100 may be detachable from the bracket 200 and may be connected to the cover 300 to be opened and closed. For example, the rear surface 101 of the body 100 may be connected to the bracket 200. In addition, the cover 300 may be connected to a front side of the body 100, opposite to the rear surface 101, to be opened and closed. The body 100 and the cover 300 may be connected to each other through a coupler 400. The size and/or shape of the body 100 may vary depending on the structure S and the surveillance camera 20, and may have, for example, a rectangular parallelepiped box shape.

The body 100 may include the first accommodation groove 110, the hook 120, a body cover 130, a first rib 140, a seating groove 150, a second accommodation groove 160, a second rib 170, a first body hole 180, and a second body hole 190.

The first accommodation grooves 110 may be formed in the body 100 and may accommodate at least a part of the bracket 200 to support the body 100 to the bracket 200. For example, a plurality of first accommodation grooves 110 may be formed on the rear surface 101 of the body 100. The plurality of first accommodation grooves 110 may be formed at opposite edges of the rear surface 101 (e.g., a pair of long sides of the rear surface 101, at opposite edges of FIG. 4). When the body 100 is mounted on the bracket 200, the insertion protrusions 210 of the bracket 200 may be inserted into the first accommodation grooves 110 so that the body 100 may be temporarily fixed to the bracket 200 at a first position or the body 100 may be fixed to the bracket 200 at a second position. Two first accommodation grooves 110 may be formed at opposite edges of the body 100 in the width direction (e.g., the X-axis direction of FIG. 4). The plurality of first accommodation grooves 110 may be respectively formed between the rear surface 101 of the body 100 and the plurality of body covers 130 spaced apart from the rear surface 101.

Each of the first accommodation grooves 110 may have a bottom part and a side part that are open to an outside of the body 100. For example, as shown in FIG. 5, the lower part of the first accommodation groove 110 may be opened in the height direction of the body 100 (e.g., the Y-axis direction of FIG. 5), and the outer part thereof may be opened in the width direction of the body 100 (e.g., the X-axis direction of FIG. 5). Meanwhile, the top surface and the other side surfaces opposite to the open portions of the first accommodation groove 110 may be blocked. Therefore, when attaching and detaching the body 100 to and from the bracket 200, the insertion protrusion 210 may be inserted and detached through the bottom part and one side part of the first accommodation groove 110.

At least one hook 120 may be formed in the body 100 and may connect and/or support the body 100 and the bracket 200 with each other. For example, as shown in FIG. 4, the hook 120 may be formed on any one of the long sides of the body 100. For example, the hook 120 may be positioned between the plurality of first accommodation grooves 110 in the height direction of the body 100 (e.g., the Y-axis direction of FIG. 4). When the hook 120 mounts the body 100 to the bracket 200, the hook 120 may temporarily fix the body 100 to the bracket 200 at a first position. For example, the hook 120 may be supported by any one of the plurality of support protrusions 220 of the bracket 200, so that the body 100 may be supported by the bracket 200 in the height direction (e.g., the Y-axis direction of FIG. 4). In addition, the hook 120 may allow the body 100 to move from the first position to a second position with respect to the bracket 200. For example, in a state in which the hook 120 is supported by the support protrusion 220 at the first position, when the position and/or shape of the hook 120 is deformed, the hook 120 may be separated from the support protrusion 220. As the body 100 is no longer supported by the bracket 200 in the height direction of the body 100, the body 100 may descend downward and move to the second position.

The hook 120 may include a portion which is at least partially deformable. For example, the hook 120 may include an unmodified rigid body at a portion supporting the support protrusion 220, and a portion of the hook 120 may include an elastic body that may be deformed according to an external force. Therefore, when the user applies an external force to the hook 120, such as pressing or towing the hook 120, the state between the hook 120 and the support protrusion 220 changes as the deformable part is deformed, and the position of the body 100 may change.

The hook 120 may be accommodated in the second accommodation groove 160 of the body 100. For example, as shown in FIG. 5, the second accommodation groove 160 may be formed in the rear surface 101 and the side surface 102 of the body 100, and the hook 120 may be fitted into the second accommodation groove 160. The hook 120 may be movable or deformed while being accommodated in the second accommodation groove 160.

The hook 120 may include a hook body 121, a deformable body 122, and a hook protrusion 123.

The hook body 121 may be a portion accommodated in the second accommodation groove 160 and may support the deformable body 122 and the hook protrusion 123. For example, as shown in FIG. 5, the hook body 121 may have an L shape corresponding to the shape of the second accommodation groove 160. A portion (e.g., a long portion) of the hook body 121 may be accommodated in the second accommodation groove 160 formed in the rear surface 101 of the body 100, and another portion (e.g., a short portion) of the hook body 121 may be accommodated in the second accommodation groove 160 formed in the side surface 102 of the body 100. The user may press a portion of the hook body 121 (e.g., a short portion of the hook body 121) toward the inside of the body 100 and moves the hook body 121 so that the hook 120 may be separated from the support protrusion 220.

The hook body 121 may include an insertion hole 1211. For example, as shown in FIG. 5, the insertion hole 1211 may have a long hole shape in the hook body 121 in the width direction of the body 100 (e.g., the X-axis direction of FIG. 5). The insertion hole 1211 may be inserted into a connection protrusion 161 to prevent the hook 120 from being separated from the second accommodation groove 160 and to allow the hook 120 to move. For example, when the hook 120 is pressed at the first position, the hook 120 may move in a state where the connection protrusion 161 is inserted into the insertion hole 1211.

The deformable body 122 may be connected to the hook body 121 and may be deformed by an external force. For example, as shown in FIG. 5, a plurality of deformable bodies 122 may be formed at the end portion of the hook body 121 (e.g., the end portion of the long portion of the hook body 121). An end portion of the deformable body 122 may be supported by an inner surface of the second rib 170. Therefore, when the user presses the hook 120, the deformable body 122 may bend and the hook body 121 may move toward the inside of the body 100. Thereafter, when the user does not press the hook 120, the hook body 121 may return to its original position by the restoring force of the deformable body 122. For example, each of the deformable bodies 122 may have a curved shape.

The hook protrusion 123 may be connected to the hook body 121 and supported by the support protrusion 220. For example, as shown in FIG. 5, the hook protrusion 123 may protrude from one surface of the hook body 121 (e.g., the front surface of FIG. 5). In a state in which the hook 120 is not pressed (or at the first position), the hook protrusion 123 may be at a position corresponding to a sliding gap G between the first rib 140 and the second rib 170. Accordingly, the hook protrusion 123 may be supported on the support protrusion 220 at the first position. However, the hook protrusion 123 may be supported on the support protrusion 220 and a part of the hook body 121 may be also supported on the support protrusion 220.

A plurality of body covers 130 may be formed on the rear surface 101 of the body 100 to correspond to the first accommodation groove 110, respectively. For example, as shown in FIG. 4, the body cover 130 may be spaced apart from the rear surface 101 and a first accommodation groove 110 may be formed therebetween. The body cover 130 may support the insertion protrusion 210 so that the insertion protrusion 210 is not separated in the thickness direction (e.g., the Z-axis direction of FIG. 5) of the body 100 in a state where the insertion protrusion 210 is inserted into the first accommodation groove 110. Therefore, at the first position and the second position, the position of the body 100 in the thickness direction (e.g., the Z-axis direction of FIG. 5) with respect to the bracket 200 of the body 100 may be fixed.

The first rib 140 may extend along an edge of the body 100. For example, as shown in FIG. 4, the first rib 140 may protrude along an outer edge of the rear surface 101 of the body 100. When the body 100 is mounted on or in a state in which the body 100 is mounted on the bracket 200, the first rib 140 may allow the body 100 to move smoothly without being separated from the bracket 200. For example, the first rib 140 may surround the outside of the insertion protrusion 210 and/or the support protrusion 220 of the bracket 200. Therefore, the body 100 may be supported so as not to be separated from the bracket 200 at the first position. In addition, when the body 100 moves from the first position to the second position, the body 100 may be supported so as not to be separated from the bracket 200. In addition, the insertion protrusion 210 and/or an outer surface of the support protrusion 220 may be in contact with an inner surface of the first rib 140, and thus the body 100 may stably slide with respect to the bracket 200.

The first rib 140 may form a sliding gap G with respect to the body cover 130 and the second rib 170. For example, as shown in FIG. 5, the inner surface of the first rib 140 may be spaced apart from the outer surfaces of the body cover 130 and the second rib 170 toward the inside in the width direction of the body 100 (e.g., the X-axis direction of FIG. 5), and a sliding gap G may be formed therebetween. As the body 100 slides with respect to the bracket 200 while the insertion protrusion 210 and the support protrusion 220 are inserted into the sliding gap G, the body 100 may move stably without being separated from the bracket 200.

The first rib 140 may include a rib slit 141. For example, as shown in FIG. 5, the rib slit 141 may be formed in the first rib 140 to correspond to the first accommodation groove 110. For example, a respective rib slit 141 may be formed for each of the plurality of first accommodation grooves 110.

The first rib 140 may extend continuously or discontinuously along an outer edge of the rear surface 101 of the body 100. For example, the first rib 140 may be cut off to allow the hook 120 to move in a portion corresponding to the second accommodation groove 160 in which the hook 120 is seated, and may be continuously connected in the remaining portions.

A plurality of seating grooves 150 may be formed on the rear surface 101 of the body 100 to correspond to the first accommodation grooves 110, respectively. For example, as shown in FIG. 5, the seating groove 150 may be formed to be concave on the rear surface 101 to form a step with the rear surface 101. When the insertion protrusion 210 is inserted into the first accommodation groove 110, the insertion protrusion 210 may be stably inserted into the seating groove 150 without interfering with or colliding with the rear surface 101 or the body cover 130.

The second accommodation groove 160 may be formed in the body 100 and may accommodate the hook 120. For example, as shown in FIG. 5, the second accommodation groove 160 may be formed in the rear surface 101 and the side surface 102 of the body 100 and may include an L-shaped groove. The second accommodation groove 160 may include the connection protrusion 161, and the connection protrusion 161 may be inserted into the insertion hole 1211 of the hook 120.

The second rib 170 may protrude along the edge of the second accommodation groove 160. For example, as shown in FIG. 5, the second rib 170 may protrude along the edge of the second accommodation groove 160 and may be spaced apart from the first rib 140 to form the sliding gap G therebetween. An inner side surface of the second rib 170 may support the deformable body 122 of the hook 120.

Although the body 100 includes one hook 120 in the drawings, the number of hooks 120 may be two or more. For example, one hook 120 may be formed on each of a pair of long sides of the body 100, or a plurality of hooks 120 may be formed for each long side. The second accommodation grooves 160 and the second ribs 170 may also be formed in the body 100 in the same number as the hooks 120.

The body 100 may include a plurality of body holes (e.g., a first body hole 180 and a second body hole 190).

A plurality of first body holes 180 may be formed in the body 100 and may be passages through which wires W pass. For example, as shown in FIG. 6, a plurality of first body holes 180 may be formed in the inner lower portion of the body 100 to face the inner space of the body 100. While the body 100 is temporarily fixed to the bracket 200, the wire W may be inserted into the inner space of the body 100 through the first body hole 180 to be connected to various electronic/electrical devices. The plurality of first body holes 180 may correspond to a plurality of second bracket holes 250 of the bracket 200. For example, while the body 100 is temporarily fixed to the bracket 200, the wire W may be inserted through the second bracket hole 250, and the wire W may be inserted into the inner space of the body 100 through the first body hole 180.

A plurality of second body holes 190 may be formed in the body 100 and may be passages through which wires W pass. For example, as shown in FIG. 6, a plurality of second body holes 190 may be formed in the rear surface 101 of the body 100. For example, the second body hole 190 may have a knock-out structure that is closed before use, and as required, the second body hole 190 may be opened to insert the wire W into the second body hole 190. The plurality of second body holes 190 may correspond to a plurality of first bracket holes 240 of the bracket 200. For example, while the body 100 is temporarily fixed to the bracket 200, the first bracket hole 240 and the second body hole 190 may be opened, and then the body 100 may be moved to the bracket 200 to be finally fixed to the bracket 200, and then the wire W may be inserted into the inner space of the body 100 by inserting the wire W into the first bracket hole 240 and the second body hole 190.

The bracket 200 may be mounted on a structure S, such as a wall, a ceiling, a corner, or an external device, and fastened to the body 100 to support the cabinet 10 on the structure S. For example, the body 100 may be mounted on the bracket 200 in a state in which the bracket 200 is pre-mounted on a structure S such as a pillar, a wall, or the like through a bolt, a welding, an adhesive, or the like.

As shown in FIG. 7, the bracket 200 may include a bracket body 201, a bracket head 202, a bracket bottom 203, and a bracket plate 204.

The bracket body 201 may hold and/or support other components of the bracket 200. The bracket body 201 may have a shape corresponding to the rear surface 101 of the body 100, and may support an insertion protrusion 210, a support protrusion 220, and a guide protrusion 230. For example, as shown in FIG. 7, insertion protrusions 210, support protrusions 220, and guide protrusions 230 may be formed on a pair of long sides of the bracket body 201, respectively.

The bracket head 202 may be connected to a top end of the bracket body 201 and may support an upper portion of the rear surface 101 of the body 100.

The bracket bottom 203 may extend downward from a bottom end of the bracket body 201 and may support a lower portion of the rear surface 101 of the body 100. A plurality of first bracket holes 240 and a plurality of second fastening holes 205 may be formed in the bracket bottom 203.

The bracket plate 204 may extend inward from the bracket bottom 203 in the thickness direction of the body 100 (e.g., the Z-axis direction of FIG. 7). The bracket plate 204 may surround the lower end portion of the body 100 in a state in which the body 100 and the bracket 200 are coupled to each other, and may include a plurality of second bracket holes 250.

The bracket 200 may include the insertion protrusions 210, the support protrusions 220, the guide protrusions 230, the first bracket holes 240, and the second bracket holes 250.

One or more insertion protrusions 210 may be included in the bracket 200 and may support the body 100. For example, as shown in FIG. 7, one or more insertion protrusions 210 may be formed on opposite edges of the bracket 200 (e.g., a pair of long sides of the bracket body 201), respectively. The insertion protrusion 210 may be inserted into the first accommodation groove 110 of the body 100 to prevent the body 100 from being separated from the bracket 200 in the thickness direction (e.g., a Z-axis direction of FIG. 7).

A plurality of insertion protrusions 210 may be provided. The insertion protrusion 210 may include a plurality of first insertion protrusions 211 and a plurality of second insertion protrusions 212. The first insertion protrusion 211 may be formed at an upper portion of the bracket 200 and inserted into the first accommodation groove 110 formed at an upper portion of the body 100. The second insertion protrusion 212 may be formed under the first insertion protrusion 211, for example, on a fourth support protrusion 224 to be described later. The second insertion protrusion 212 may be inserted into the first accommodation groove 110 formed in a lower portion of the body 100. For example, the insertion protrusion 210 may include four insertion protrusions 210 formed in two at each edge of either side in the width direction of the bracket 200. In addition, the plurality of support protrusions 220 each may be formed between two insertion protrusions 210 formed on at least one of both edges in the width direction of the body 100.

The insertion protrusion 210 may include a first portion 2101 and a second portion 2102.

For example, as shown in FIG. 7, the first portion 2101 may extend from the bracket 200 in the first direction (e.g., the Z-axis direction of FIG. 7 or the thickness direction of the body 100), and the second portion 2102 may extend from the end portion of the first portion 2101 in the second direction (e.g., the X-axis direction of FIG. 7 or the width direction of the body 100) crossing the first direction. The first portion 2101 may not be inserted into the first accommodation groove 110 and may be inserted into the sliding gap G to assist movement of the body 100 with respect to the bracket 200. The second portion 2102 may be a portion that is inserted into and detached from the first accommodation groove 110 according to a position with respect to the bracket 200 of the body 100. For example, at least a part of the first portion 2101 (e.g., the upper portion) may be inserted into the first accommodation groove 110 at the first position, and the entire second portion 2102 may be inserted into the first accommodation groove 110 at the second position.

One or more support protrusions 220 may be included in the bracket 200 and may support the body 100. For example, the insertion protrusions 210 may be formed on opposite edges of the bracket 200 (e.g., a pair of long sides of the bracket body 201). For example, as shown in FIG. 7, the insertion protrusion 210 may be formed on any one of a pair of long sides of the bracket 200. The insertion protrusion 210 may protrude from the bracket 200 (e.g., the bracket body 201) toward the body 100, and may be inserted into the sliding gap G to assist movement of the body 100 with respect to the bracket 200.

The support protrusion 220 may include a plurality of support protrusions. The plurality of support protrusions 220 may be formed between the plurality of insertion protrusions 210 in the height direction (e.g., the Y-axis direction of FIG. 7) of the bracket 200. For example, the support protrusions 220 may include a first support protrusion 221, a second support protrusion 222, a third support protrusion 223, and a fourth support protrusion 224.

The first support protrusion 221 may be formed in the center of the bracket 200 in the height direction (e.g., the Y-axis direction of FIG. 7), may be inserted into the sliding gap G, and may support the hook 120. For example, the first support protrusion 221 may support a lower end of the hook 120 at a first position.

The second support protrusion 222 may be formed between the first insertion protrusion 211 and the first support protrusion 221 and inserted into the sliding gap G. The second support protrusion 222 may be spaced apart from the first support protrusion 221 in the height direction of the bracket 200 (e.g., in the Y-axis direction of FIG. 7), and the hook 120 may be positioned between the first support protrusion 221 and the second support protrusion 222 at the second position.

The third support protrusion 223 may be formed between the first support protrusion 221 and the second insertion protrusion 212 and may be inserted into the sliding gap G.

The fourth support protrusion 224 may be formed under the second insertion protrusion 212 and inserted into the sliding gap G. At the first position with respect to the bracket 200 of the body 100, the fourth support protrusion 224 may not be inserted into the sliding gap G, and when the body 100 moves to the second position, the fourth support protrusion 224 may be inserted into the sliding gap G.

One or more guide protrusions 230 may be included in the bracket 200 and may support the body 100. For example, the guide protrusions 230 may be formed on opposite edges of the bracket 200 (e.g., a pair of long sides of the bracket body 201). For example, as shown in FIG. 7, the guide protrusion 230 may be formed on any one of the pair of long sides of the bracket 200 in which the support protrusion 220 is not formed. The guide protrusion 230 may be inserted into the sliding gap G to assist movement of the body 100 with respect to the bracket 200. The guide protrusion 230 may be continuously extended without being segmented or broken so that the body 100 may move more stably in a state where the body 100 is connected to the bracket 200.

Alternatively, without the guide protrusion 230, a plurality of support protrusions 220 may be formed on both long sides of the bracket 200. For example, a second support protrusion 222, a first support protrusion 221, a third support protrusion 223, and a fourth support protrusion 224 may be formed in order on each of a pair of long sides of the bracket 200.

The bracket 200 may include a plurality of bracket holes (e.g., a first bracket hole 240 and a second bracket hole 250).

A plurality of first bracket holes 240 may formed in the bracket 200 and may be passages through which wires W pass. For example, as shown in FIG. 7, the plurality of first bracket holes 240 may be formed in the bracket bottom 203 and may correspond to the plurality of second body holes 190, respectively.

A plurality of second bracket holes 250 may formed in the bracket 200 and may be passages through which wires W pass. For example, as shown in FIG. 7, the plurality of second bracket holes 250 may formed in the bracket plate 204 and may correspond to the plurality of first body holes 180, respectively.

The first bracket holes 240 and the second bracket holes 250 may include a knockout structure to be opened by tearing.

At the first position with respect to the bracket 200 of the body 100, the user may open the second bracket hole 250 to insert the wire W into the second bracket hole 250 and then insert the wire W into the body 100 through the first body hole 180. In addition, the user may open the first bracket hole 240 to insert an additional wire W into the first bracket hole 240, and then insert the additional wire W into the body 100 through the second body hole 190.

The cover 300 may be connected to the body 100 and may open and close the inside of the body 100. For example, as shown in FIG. 2, the cover 300 may be mounted on the opposite side of the bracket 200, that is, on a portion of the body 100 to be opened and closed. The cover 300 may be hinge-coupled to the body 100 through the coupler 400. The connector 500 may be formed on the front surface of the cover 300, and the surveillance camera 20 and the electronic/electrical equipment in the body 100 may be connected to each other via the connector 500. The connector 500 may include a plurality of terminals.

The coupler 400 may connect and/or fix the body 100 and the cover 300. For example, the coupler 400 may include a plurality of couplers, and some of the plurality of couplers 400 may include hinges that connect the cover 300 to the body 100 such that the cover 300 may rotate with respect to the body 100, and the other of the plurality of couplers 400 may fix the cover 300 to the body 100 in a state in which the cover 300 is closed on the body 100.

The couplers 400 may include a first coupler 410, a second coupler 420, and a third coupler 430.

The first coupler 410 may include a hinge that couples the body 100 with the cover 300. For example, a plurality of first couplers 410 may be provided, and one first coupler 410 may be formed in each of upper and lower portions in the height direction (e.g., the Y-axis direction of FIG. 16) of the cabinet 10. For example, the first coupler 410 may be a shaft hinge.

The first coupler 410 may include a body coupler 411, a cover coupler 412, and a shaft 413.

A plurality of body couplers 411 may be formed on the side surface of the body 100, and a plurality of cover couplers 412 may be formed on the side surface of the cover 300 to correspond to the plurality of body couplers 411. Each body coupler 411 may be rotatably connected to each cover coupler 412 via a shaft 413.

The body coupler 411 may include a first protrusion 4111 and a first concave portion 4112, and the cover coupler 412 may include a second protrusion 4121 and a second concave portion 4122. The shaft 413 may be inserted into the body coupler 411 and the cover coupler 412 in a state in which the protrusions and the concave portions are engaged with each other. For example, as shown in FIG. 16, the first protrusion 4111 may be inserted into the second concave portion 4122, the second protrusion 4121 may be inserted into the first concave portion 4112, and the shaft 413 may be inserted into the first protrusion 4111 and the second protrusion 4121.

The first coupler 410 may limit a rotation angle with respect to the body 100 of the cover 300. For example, as shown in FIG. 17, when the body coupler 411 and the cover coupler 412 are connected to each other, the body coupler 411 may no longer rotate as the body coupler 411 contacts the edge of the cover coupler 412. For example, as the outer surface of the body coupler 411 contacts the edge between the outer surface of the cover coupler 412 and the second concave portion 4122, the rotation angle of the body coupler 411 may be limited. For example, a maximum rotation angle of the cover 300 with respect to the first coupler 410 may be in a range of 80 degrees to 120 degrees. For example, the maximum rotation angle of the cover 300 with respect to the first coupler 410 may be 105 degrees. Although only a cross-section corresponding to the first protrusion 4111 and the second concave portion 4122 is shown in FIG. 17, the second protrusion 4121 and the first concave portion 4112 may also operate in the same manner. For example, as the outer surface of the cover coupler 412 contacts the edge between the outer surface of the body coupler 411 and the first concave portion 4112, the rotation angle of the body coupler 411 may be limited.

The second coupler 420 may include a hinge that couples the body 100 to the cover 300. For example, the second coupler 420 may be positioned between the plurality of first couplers 410. For example, the second coupler 420 may be a torque hinge.

A plurality of third couplers 430 may be formed on opposite sides of the first coupler 410 and the second coupler 420. For example, as illustrated in FIG. 2, the first coupler 410 and the second coupler 420 may be formed on one side of the body 100 and the cover 300, and the third coupler 430 may be formed on an opposite side of the body 100 and the cover 300, as illustrated in FIG. 3. The third coupler 430 may be connected to the cover 300 and the body 100 by a bolt or the like while the cover 300 closes the body 100 to fix the cover 300 and the body 100 to each other.

The connector 500 is on the front surface of the cover 300, and the surveillance camera 20 and/or a mounting structure such as a bracket or various accessories for supporting the surveillance camera 20, may be mounted on the connector 500. For example, as shown in FIG. 2, the connector 500 may include a plurality of terminal holes 510 and a plurality of mounting holes 520 to which the surveillance camera 20 is connected. Various cables such as a communication line and a power line may be connected to the surveillance camera 20 through the terminal holes 510. The terminal holes 510 may be formed inside a groove portion 530 formed by being recessed in the surface of the connector 500. Therefore, when the surveillance camera 20 and/or the mounting structure are mounted on the connector 500, a length of the cover 300 protruding in the front direction may be reduced by a terminal portion of the surveillance camera 20 and/or the mounting structure.

The mounting holes 520 may be holes for mounting the surveillance camera 20 and/or the mounting structure to the connector 500. The mounting holes 520 may include a plurality of mounting holes arranged in different positions to mount various sizes and types of surveillance cameras 20 and/or mounting structures. For example, as shown in FIG. 2, the plurality of mounting holes 520 may be formed around the terminal holes 510 at different distances from the terminal holes 510. Therefore, even for surveillance cameras 20 and/or mounting structures of different sizes and shapes may be mounted on the connector 500 without adding a separate coupler or the like.

The fastening member 600 may fix the body 100 and the bracket 200 to each other. For example, in the second position with respect to the bracket 200 of the body 100, the fastening member 600 may be inserted into the body 100 and the bracket 200 to fix the two. For example, as shown in FIG. 15, the fastening member 600 may have a bolt shape and may be inserted into a first fastening hole 103 of the body 100 and a second fastening hole 205 of the bracket 200.

As shown in FIG. 15, the fastening member 600 may include a bolt head 610, a support spring 620, and a washer 630.

In a state in which the fastening member 600 is inserted into the first fastening hole 103 and the second fastening hole 205, the bolt head 610 protrudes toward the inner space of the body 100, and the washer 630 may be inserted into the bolt head 610. The support spring 620 may be wound around the fastening member 600, and an end portion of the support spring 620 may be supported by the washer 630.

The support spring 620 may separate the main body of the fastening member 600 from the inner surface of the first fastening hole 103 until the fastening member 600 is completely inserted into the first fastening hole 103 and the second fastening hole 205. For example, before the body 100 is mounted on the bracket 200, a portion of the fastening member 600 may be already inserted into the first fastening hole 103 and may not be inserted into the second fastening hole 205. Therefore, the fastening member 600 does not impede the movement of the body 100 to the bracket 200, and in this state, the main body of the fastening member 600 may not contact the inner surface of the first fastening hole 103. When the body 100 moves to the second position with respect to the bracket 200, the fastening member 600 may be pushed up to the second fastening hole 205 and the bolt head 610 may be turned to fix the body 100 and the bracket 200. Alternatively, before mounting the body 100 to the bracket 200, the fastening member 600 may be separated from the first fastening hole 103 and the second fastening hole 205. When the body 100 moves to the second position with respect to the bracket 200, the cover 300 may be opened and the fastening member 600 may be inserted into the first fastening hole 103 and the second fastening hole 205 by inserting the fastening member 600 into the body 100.

Next, an installation operation of the cabinet 10 is described with reference to FIGS. 1 to 17.

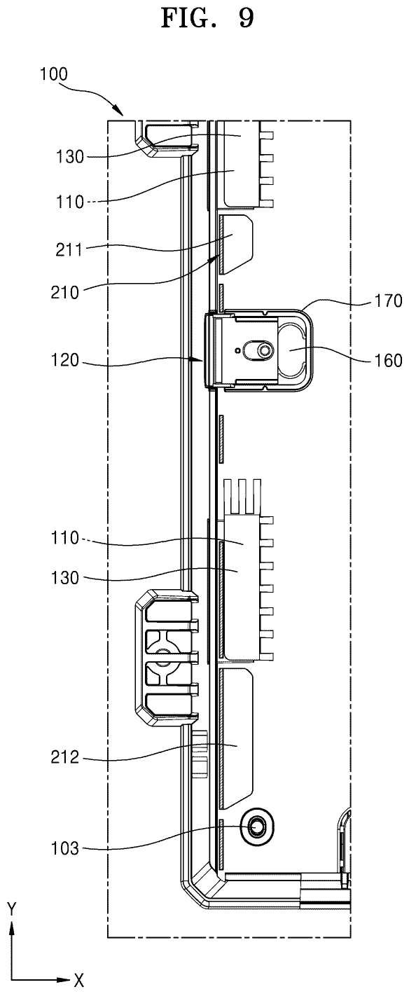

First, as shown in FIG. 8, the body 100 approaches the bracket 200. Here, the bracket 200 may be mounted on the structure S, and various electronic/electrical equipment may be accommodated in the body 100. In addition, the cover 300 may be coupled to the body 100 via the coupler 400. The user may make the rear surface 101 of the body 100 contact the bracket 200 while the user is gripping the body 100. In this state, the bracket 200 may not be fixed to the body 100. For example, as shown in FIG. 9, the insertion protrusion 210 may not be inserted into the first accommodation groove 110. For example, both the first insertion protrusion 211 and the second insertion protrusion 212 may not be inserted into the first accommodation grooves 110. In addition, some portions of the first insertion protrusion 211 and the second insertion protrusion 212 (e.g., the first portion 2101) may be inserted into the sliding gap G. In addition, some of the plurality of support protrusions 220 may be inserted into the sliding gap G. For example, each of the first support protrusion 221, the second support protrusion 222, and the third support protrusion 223 may be inserted into the sliding gap G. In addition, the guide protrusion 230 may also be inserted into the sliding gap G. The user may temporarily align the position of the body 100 with respect to the bracket 200 by inserting the support protrusion 220 and the guide protrusion 230 into the sliding gap G of the body 100.

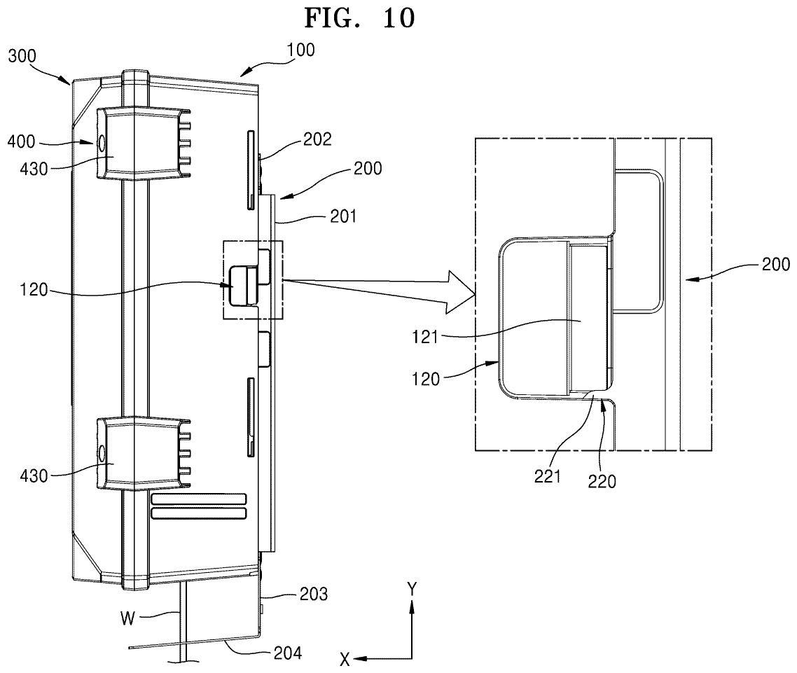

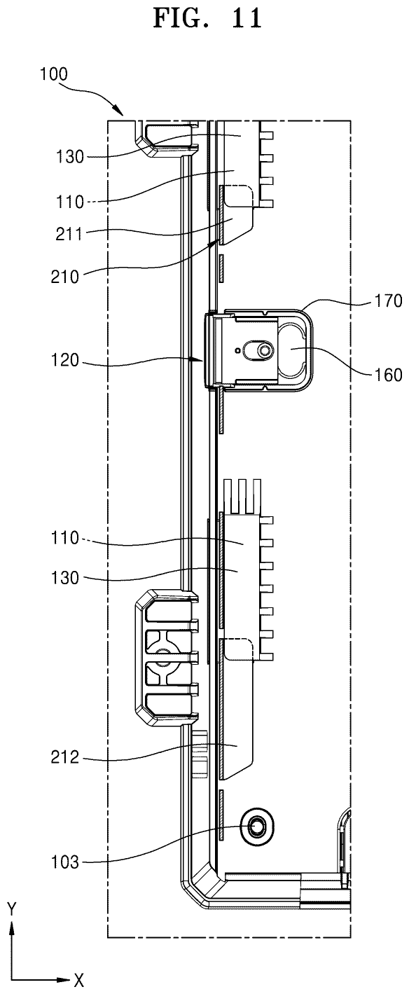

Next, the body 100 may be lowered in the height direction of the bracket 200 (e.g., in the Y-axis direction of FIG. 10). For example, the user may slowly lower the body 100 that is being held. Accordingly, as shown in FIG. 10, the hook 120 may be supported on the support protrusion 220 (e.g., the first support protrusion 221) as the body 100 descends downward by its own weight. Therefore, the body 100 may be temporarily fixed (initially fixed) to the bracket 200 in the height direction of the body 100 (e.g., the Y-axis direction of FIG. 10). In addition, as shown in FIG. 11, at least a portion of the insertion protrusion 210 may be inserted into the first accommodation groove 110. For example, the upper portion of the second portion 2102 of each of the first insertion protrusion 211 and the second insertion protrusion 212 may be inserted into the first accommodation groove 110 to be covered by the body cover 130. In this way, while the hook 120 is supported by the support protrusion 220 and a portion of the insertion protrusion 210 is inserted into the first accommodation groove 110, the position of the body 100 becomes the first position (set-up position) with respect to the bracket 200 of the body 100. At the first position, the body 100 may be temporarily fixed to the bracket 200 in the thickness direction of the body 100 (e.g., in the Z-axis direction of FIG. 11). In this state, the bracket plate 204 of the bracket 200 may be spaced apart from the bottom portion of the body 100.

At the first position, one or more insertion protrusions 210 are respectively inserted into one or more first accommodation grooves 110 and respectively spaced apart from the top ends of the first accommodation groove 110, and the hook 120 may be supported on the support protrusion 220 of any one of the plurality of support protrusions 220.

In the temporarily fixed state, the body 100 and the bracket 200 may be in a state in which the body 100 and the bracket 200 are not finally fixed via bolts, welding, adhesives, or the like. In this way, the wire W may be arranged in the temporarily fixed state before the body 100 is finally fixed to the bracket 200. For example, after inserting the wire W through the second bracket hole 250 formed in the bracket plate 204 and the first body hole 180, the wire W may be connected to the inside of the body 100. Since the body 100 and the bracket 200 (e.g., bracket plate 204) are spaced apart from each other in the temporarily fixed state, the user may easily arrange the wire W. In addition, since the body 100 is temporarily fixed to the bracket 200 or not permanently fixed, the user may more easily align the wire W while finely adjusting the position of the body 100.

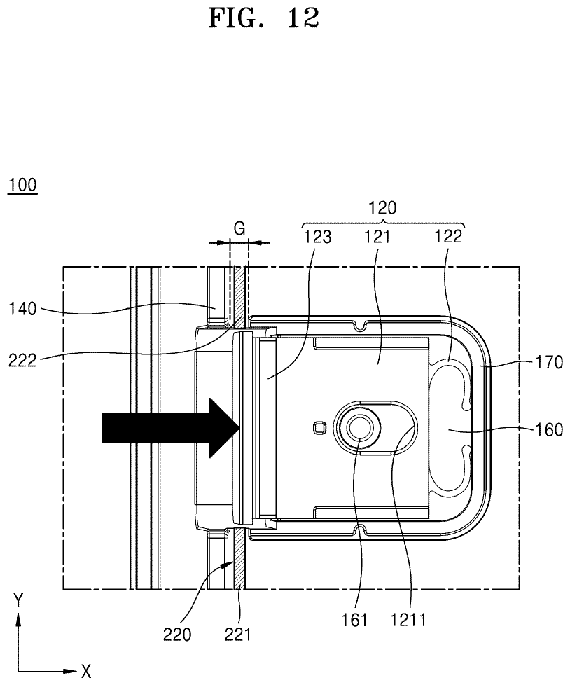

When the temporary fixing and the alignment of the wire W are completed, the user may move the body 100 to the second position (installation position) with respect to the bracket 200. For example, as shown in FIG. 12, the user may press the hook 120. As the hook 120 is pressed inward from the side surface of the body 100, the deformable body 122 of the hook 120 may be pressed against the second rib 170 to be deformed. Therefore, the hook body 121 and the hook protrusion 123 move inside the body 100 (e.g., in the X-axis direction of FIG. 12) and is separated from the support protrusion 220 (e.g., first support protrusion 221). Therefore, the bracket 200 no longer supports the body 100 in the height direction of the body 100 (e.g., the Y-axis direction of FIG. 12), and the body 100 descends.

When the body 100 moves from the first position to the second position, the body 100 may not be separated from the bracket 200. For example, at least some portions of the one or more insertion protrusions 210 accommodated in the one or more first accommodation grooves 110 at the first position may be inserted into the first accommodation grooves 110, respectively, and when the body 100 moves from the first position to the second position, the one or more insertion protrusions 210 may maintain a state in which the one or more insertion protrusions 210 are not separated from the first accommodation grooves 110. For example, when the body 100 moves from the first position to the second position, the plurality of support protrusions 220 inserted into the sliding gap G may not be separated from the sliding gap G.

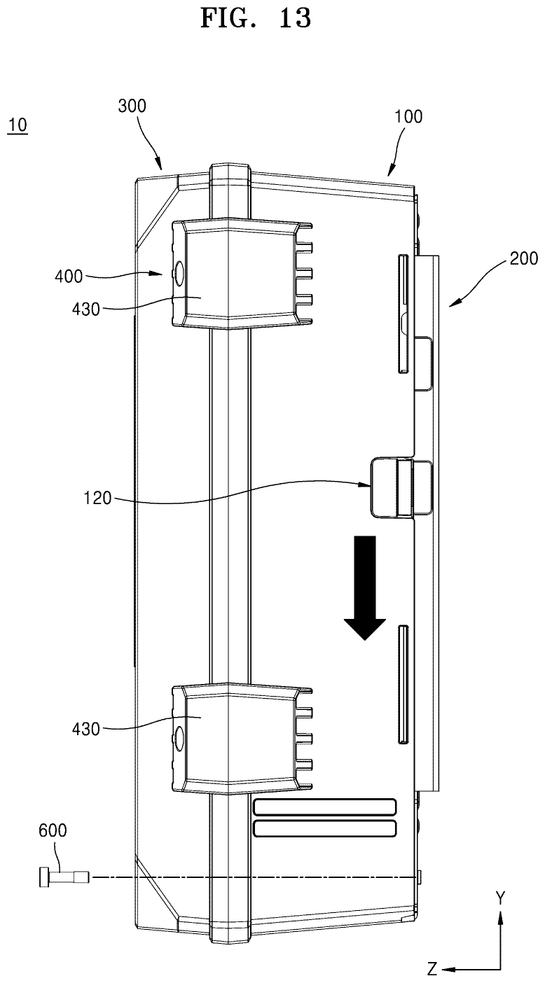

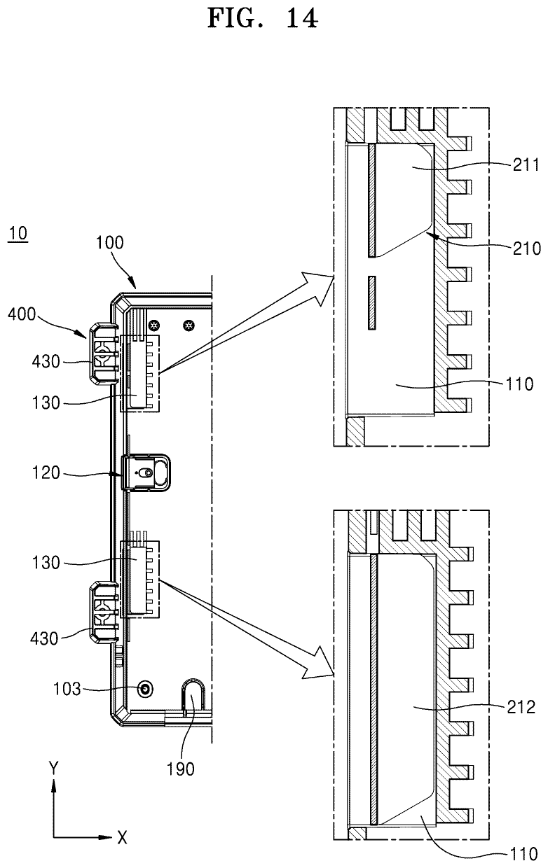

In addition, as shown in FIG. 13, the body 100 moves to the second position with respect to the bracket 200. At the second position, the bracket plate 204 may be in contact with the bottom surface of the body 100, and all of the plurality of support protrusions 220 may be inserted into the sliding gap G. In addition, all of the plurality of insertion protrusions 210 may be inserted into the first accommodation grooves 110. For example, as illustrated in FIG. 14, the top end of the first insertion protrusion 211 and the top end of the second insertion protrusion 212 may be in contact with the top ends of the first accommodation grooves 110, respectively. In addition, the second portions 2102 of the first insertion protrusion 211 and the second insertion protrusion 212 may be all covered by the body cover 130 and may not be exposed to the outside. As the plurality of insertion protrusions 210 are inserted into the first accommodation grooves 110, respectively, the position of the body 100 may be fixed in each of the height direction and the thickness direction of the body 100.

At the second position, one or more insertion protrusions 210 may be inserted to the top ends of one or more first accommodation grooves 110, and the hook 120 may be positioned below the support protrusion 220 that supports the hook 120 at the first position.

Next, the body 100 and the bracket 200 may be fastened using the fastening member 600. The fastening member 600 may be inserted into the first fastening hole 103 of the body 100 and the second fastening hole 205 of the bracket 200 to fix the body 100 and the bracket 200. The fastening member 600 may be inserted into the first fastening hole 103 before the body 100 is mounted on the bracket 200, or when the body 100 moves to the second position with respect to the bracket 200, the fastening member 600 may be inserted into the first fastening hole 103 and the second fastening hole 205. When the fastening member 600 is inserted into the first fastening hole 103 and the second fastening hole 205, the user may fix the fastening member 600 to the first fastening hole 103 and the second fastening hole 205 by turning the bolt head 610.

Technology of a comparative embodiment has the hassle of repeatedly installing and removing high-weight surveillance cameras in and from the cabinet, and worker safety may be a problem in this process. However, when the cabinet 10 for surveillance cameras is fastened to the bracket 30 according to embodiments of the present disclosure, the final installation can be completed after performing installation such as cable work without separating the cabinet 10 for surveillance cameras from the bracket 30 after temporary fixing the cabinet to the bracket. In addition, even if the surveillance camera 20, which may be heavy or bulky, is mounted on the cabinet 10 (e.g., a surveillance camera cabinet), the installation and disassembly work may be stably performed.

The cabinet for a surveillance camera according to embodiments may stably perform operations such as cable alignment while leaving the body and bracket in a temporary fixed state before final fixing.

The cabinet for a surveillance camera according to embodiments may fix the body and the bracket by lowering the body without having to separate the body from the bracket for final fixing after temporary fixing.

However, the effects of embodiments of the present disclosure are not limited to the effects described above, and other technical effects of embodiments of the present disclosure not mentioned will be clearly understood by those skilled in the art from the above description of the present disclosure.

Embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A cabinet for a surveillance camera, the cabinet comprising:
a body;
a bracket configured to be connected to a rear surface of the body; and
a cover configured to be connected to a front surface of the body to be opened and closed,
wherein the body comprises at least one first accommodation groove in a rear edge of the body,
wherein the bracket comprises:
at least one insertion protrusion respectively corresponding to the at least one first accommodation groove, and
at least one support protrusion at an edge of the bracket to face the rear surface of the body at a position spaced apart from the at least one first accommodation groove,
wherein the body is configured to be coupled to the bracket at a first position with respect to the bracket, and then at a second position with respect to the bracket,
wherein, in a case where the body is coupled to the bracket at the first position, the at least one insertion protrusion is respectively accommodated in the at least one first accommodation groove, the at least one support protrusion supports the body, and the body is temporarily fixed to the bracket at the first position, and
wherein the body is configured to, while the body is separated from the at least one support protrusion, move to the second position by sliding downward along the bracket, in a height direction of the bracket.

2. The cabinet of claim 1, wherein, in a case where the body moves from the first position to the second position, at least a part of each of the at least one insertion protrusion accommodated in the at least one first accommodation groove at the first position is maintained in the at least one first accommodation groove.

3. The cabinet of claim 1, wherein the body further comprises a first rib extending continuously or discontinuously along an outer edge of the rear surface,
wherein the at least one first accommodation groove is spaced apart from the first rib toward an inside of the body, and a sliding gap is defined by and between the first rib and the at least one first accommodation groove, and
wherein the at least one support protrusion is configured to be inserted into the sliding gap.

4. The cabinet of claim 1, wherein the body further comprises a body cover, and at least a part of the body cover is spaced apart from the rear surface of the body,
wherein the at least one first accommodation groove is between the rear surface of the body and the body cover,
wherein a lower part and a side part of the at least one first accommodation groove are open to an outside of the body, and
wherein the at least one insertion protrusion is configured to be inserted into and detached from the at least one first accommodation groove through the lower part and the side part of the at least one first accommodation groove.

5. The cabinet of claim 4, wherein the body further comprises a seating groove that is concave in the rear surface of the body and corresponds to the body cover.

6. The cabinet of claim 3, wherein each of the at least one insertion protrusion comprises:
a first portion extending in a first direction from the bracket; and
a second portion extending from the first portion in a second direction intersecting the first direction,
wherein the first portion is configured to be inserted into the sliding gap, and
wherein the second portion is configured to be inserted into the at least one first accommodation groove.

7. The cabinet of claim 1, wherein the at least one first accommodation groove comprises a plurality of first accommodation grooves that are at opposite edges of the rear surface of the body,
wherein the at least one insertion protrusion comprises a plurality of insertion protrusions that are at opposite edges of the bracket and correspond to the plurality of first accommodation grooves,
wherein the body further comprises a hook between the plurality of first accommodation grooves and connected to the rear surface of the body, and
wherein the at least one support protrusion is between the plurality of insertion protrusions in the height direction of the bracket.

8. The cabinet of claim 7, wherein the hook is configured to, in a case where the hook is pressed in a width direction of the body while the body is at the first position, deform and separate from a top of the at least one support protrusion, and
wherein the body is configured to move with respect to the bracket based on the hook deforming and separating from the top of the at least one support protrusion.

9. The cabinet of claim 7, wherein the body further comprises a second accommodation groove in a side surface of the body and the rear surface of the body, and
wherein the hook comprises:
a hook body configured to be inserted into the second accommodation groove; and
a deformable body configured to be inserted into the second accommodation groove, the deformable body extending from the hook body and comprising an elastic material.

10. The cabinet of claim 9, wherein the hook further comprises a hook protrusion protruding from the hook body toward the body,
wherein the hook protrusion is configured to be supported on the at least one support protrusion while the body is at the first position, and
wherein, based on the hook body being pressed, the deformable body is configured to be deformed and the hook protrusion is configured to be separated from the at least one support protrusion.

11. The cabinet of claim 9, wherein the body further comprises a second rib extending along an edge of the second accommodation groove and protruding from the rear surface of the body, and
wherein the deformable body comprises an end portion that has a curved shape, and the second rib is configured to support the end portion of the deformable body.

12. The cabinet of claim 9, wherein the second accommodation groove comprises a connection protrusion, and
wherein the hook body comprises an insertion hole that is configured to receive the connection protrusion, and the insertion hole has an elongated shape in a moving direction of the hook, and wherein the hook is configured to, based on the hook being pressed, move in the moving direction while the connection protrusion is in the insertion hole.

13. The cabinet of claim 1, wherein the at least one insertion protrusion comprises four insertion protrusions, and a respective two of the four insertion protrusions are on each of opposite side edges of the bracket in a width direction of the bracket, and
wherein the at least one support protrusion is between the respective two insertion protrusions in a height direction of the body.

14. The cabinet of claim 7, wherein
wherein, in the case where the body is coupled to the bracket at the first position, the at least one insertion protrusion is in the at least one first accommodation groove, respectively, and spaced apart from a top end of the at least one first accommodation groove, respectively, and the hook is supported on the at least one support protrusion, and
wherein, in a case where the body is coupled to the bracket at the second position, the at least one insertion protrusion is in the top end of the at least one first accommodation groove, respectively, and the hook is below the at least one support protrusion that supports the hook at the first position.

15. The cabinet of claim 14, wherein each of the at least one insertion protrusion comprises a first insertion protrusion, and a second insertion protrusion below the first insertion protrusion in the height direction of the bracket, and
wherein the at least one support protrusion comprises:
a first support protrusion configured to support the hook while the body is coupled to the bracket at the first position;
a second support protrusion configured to be between the first support protrusion and the first insertion protrusion while the body is coupled to the bracket;
a third support protrusion configured to be between the second support protrusion and the second insertion protrusion while the body is coupled to the bracket, and
a fourth supporting protrusion configured to be below the second insertion protrusion while the body is coupled to the bracket.

16. The cabinet of claim 1, further comprising a plurality of couplers comprising a plurality of first couplers that are configured to connect the body to the cover,
wherein the plurality of first couplers comprises:
a body coupler extending from the body and comprising a first concave portion and a first protrusion,
a cover coupler comprising a second concave portion and a second protrusion, wherein the first concave portion is configured to engage with the second protrusion, and the second concave portion is configured to engage with the first protrusion;
a shaft configured to be inserted into the first protrusion and the second protrusion in a state in which the first concave portion and the second protrusion are engaged with each other and the first concave portion and the second protrusion are engaged with each other, and
wherein the second protrusion is configured to limit a rotation angle of the cover with respect to the body by the second protrusion being in contact with the first concave portion.

17. The cabinet of claim 16, wherein the plurality of couplers further comprises a second coupler configured to connect the body to the cover, and
wherein the second coupler is spaced apart from the plurality of first couplers, is between the plurality of first couplers, and comprises a torque hinge.

18. The cabinet of claim 1, wherein the body comprises a body hole that is configured to receive a cable,
wherein the bracket comprises, at a lower portion of the bracket, a bracket hole corresponding to the body hole,
wherein the body hole is configured to receive the cable via the bracket hole while the body is at the first position, and
wherein the body is configured to be moved to the second position after the cable is inserted into the body hole through the bracket hole.

19. A cabinet for a surveillance camera, the cabinet comprising:
a body comprising a first accommodation groove; and
a bracket comprising an insertion protrusion,
wherein the body is configured to be at an initial position with respect to the bracket where the insertion protrusion is not inserted into the first accommodation groove,
wherein the body is configured to be lowered from the initial position, by its own weight, to a first position with respect to the bracket,
wherein, at the first position, the insertion protrusion is partially in the first accommodation groove,
wherein the body is configured to, in a case where the body is at the first position and pressed, lowered by its own weight to a second position with respect to the bracket,
wherein, at the second position, an amount of the insertion protrusion within the first accommodation groove is increased in comparison to when the body is at the first position, and
wherein the body is configured to not be separated from the bracket while the bracket is moving from the first position to the second position.

20. A cabinet for a surveillance camera, the cabinet comprising:
a body comprising a hook; and
a bracket comprising a support protrusion,
wherein the body is configured to be at an initial position with respect to the bracket,
wherein the body is configured to be lowered from the initial position, by its own weight, to a first position with respect to the bracket,
wherein, at the first position, the hook is supported by the support protrusion,
wherein the hook is configured to be pressed toward an inside of the body while the body is at the first position to deform the hook and separate the hook from the support protrusion,
wherein the body is configured to be lowered to a second position with respect to the bracket based on the hook being separated from the support protrusion, and
wherein the support protrusion is configured to remain in the body while the body moves from the first position to the second position.
